(19) United States
(12) Patent Application Publication
(10) Pub. No.: US 2019/0318786 A1
(43) Pub. Date: Oct. 17, 2019

(54) STORAGE DEVICE AND METHOD OF OPERATING THE SAME

(71) Applicant: SK hynix Inc., Gyeonggi-do (KR)

(72) Inventor: Gi Pyo UM, Gyeonggi-do (KR)

(21) Appl. No.: 16/172,333

(22) Filed: Oct. 26, 2018

(30) Foreign Application Priority Data
Apr. 17, 2018 (KR) 10-2018-0044375

(51) Int. Cl. G11C 16/16; G06F 3/06; G11C 7/10; G11C 16/08; G11C 16/24; G11C 16/28

(52) U.S. Cl. CPC G11C 16/16; G06F 3/064; G06F 3/0659; G11C 16/28; G11C 7/109; G11C 16/08; G11C 16/24; G06F 3/0656

(57) ABSTRACT

Provided herein may be a storage device and a method of operating the storage device. The storage device may include a memory device including a plurality of memory blocks, and a memory controller configured to control the memory device to perform a background erase operation on at least one free block of the plurality of memory blocks based on information about a size of write data to be provided to the memory device.

### CROSS-REFERENCE TO RELATED APPLICATION

The present application claims priority under 35 U.S.C. § 119(a) to Korean patent application number 10-2018-0044375, filed on Apr. 17, 2018, which is incorporated herein by reference in its entirety.

### BACKGROUND

### 1. Field of Invention

Various embodiments of the present disclosure generally relate to an electronic device. Particularly, the embodiments relate to a storage device and a method of operating the storage device.

### 2. Description of Related Art

Generally, a storage device is a device which stores data under control of a host device such as a computer, a smartphone, tablet, or a smartpad. According to the type of device provided to store data, examples of the storage device may be classified into a device such as a hard disk drive (HDD) which stores data in a magnetic disk, and a device such as a solid state drive (SSD) or a memory card which stores data in a semiconductor memory such as a nonvolatile memory.

The storage device may include a memory device in which data is stored, and a memory controller configured to store data in the memory device. The memory device may be classified into a volatile memory and a nonvolatile memory. Representative examples of the nonvolatile memory include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc.

### SUMMARY

Various embodiments of the present disclosure are directed to a storage device including a memory controller configured to control a background erase operation, and a method of operating the storage device.

An embodiment of the present disclosure may provide for a storage device including: a memory device including a plurality of memory blocks; and a memory controller configured to control the memory device to perform a background erase operation on at least one free block of the plurality of memory blocks based on information about a size of write data to be provided to the memory device.

An embodiment of the present disclosure may provide for a method of operating a memory controller configured to control a memory device including a plurality of memory blocks, the method including: obtaining information about a size of write data to be provided to the memory device; and instructing the memory device to perform a background erase operation on at least one free block of the plurality of memory blocks based on the information about the size of the write data.

An embodiment of the present disclosure may provide for a memory system including: a memory device including a plurality of memory blocks; and a controller configured to control, when accumulated size of data stored in the memory blocks becomes greater than storage capacity of a single memory block, the memory device to perform a background erase operation on one or more memory blocks storing invalid data among the memory blocks while the memory device is idle.

### BRIEF DESCRIPTION OF THE DRAWINGS

FIG. 1 is a block diagram illustrating a storage device in accordance with an embodiment of the present disclosure.

FIG. 2 is a diagram illustrating a pin configuration of a memory device of FIG. 1.

FIG. 3 is a diagram describing an input/output operation and a cell operation of the memory device during a program operation in accordance with an embodiment of the present disclosure.

FIG. 4A is a diagram illustrating the case where a program command is inputted while a normal (i.e., foreground) erase operation is performed.

FIG. 4B is a diagram illustrating the case where a program command is inputted while a background erase operation is performed, in accordance with an embodiment of the present disclosure.

FIG. 5 is a block diagram illustrating a configuration of a memory controller in accordance with an embodiment of the present disclosure.

FIG. 6 is a flowchart describing a method of operating the memory controller in accordance with an embodiment of the present disclosure.

FIG. 7 is a diagram illustrating a configuration of the memory device of FIG. 1.

FIG. 8 is a diagram illustrating an embodiment of a memory cell array of FIG. 2.

FIG. 9 is a circuit diagram illustrating any one memory block BLKa of memory blocks BLK1 to BLKz of FIG. 3, in accordance with an embodiment of the present disclosure.

FIG. 10 is a circuit diagram illustrating any one memory block BLKb of the memory blocks BLK1 to BLKz of FIG. 3, in accordance with an embodiment of the present disclosure.

FIG. 11 is a diagram illustrating an example of the memory controller of FIG. 1 in accordance with an embodiment of the present disclosure.

FIG. 12 is a block diagram illustrating a memory card system to which a storage device in accordance with an embodiment of the present disclosure is applied.

FIG. 13 is a block diagram illustrating a solid state drive (SSD) system to which the storage device in accordance with an embodiment of the present disclosure is applied.

FIG. 14 is a block diagram illustrating a user system to which the storage device in accordance with an embodiment of the present disclosure is applied.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art. It is noted that reference to “an embodiment” does not necessarily mean only one embodiment, and different references to “an embodiment” are not necessarily to the same embodiment(s).

In the drawings, dimensions of the figures may be exaggerated for clarity of illustration. It will be understood that when an element is referred to as being “between” two elements, it can be the only element between the two elements, or one or more intervening elements may also be present.

Hereinafter, embodiments will be described with reference to the accompanying drawings. Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as “first” and “second” may be used to describe various components, but they should not limit the various components. Those terms are only used for the purpose of differentiating a component from other components. For example, a first component may be referred to as a second component, and a second component may be referred to as a first component and so forth without departing from the spirit and scope of the present disclosure. Furthermore, “and/or” may include any one of or a combination of the components mentioned.

Furthermore, a singular form may include a plural form and vice versa, unless it is specifically mentioned that it is singular or plural. Furthermore, “include/comprise” or “including/comprising” used in the specification represents that one or more components, steps, operations, and elements may exist or may be added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

It is also noted that in this specification, “connected/coupled” refers to one component not only directly coupling another component but also indirectly coupling another component through an intermediate component. On the other hand, “directly connected/directly coupled” refers to one component directly coupling another component without an intermediate component.

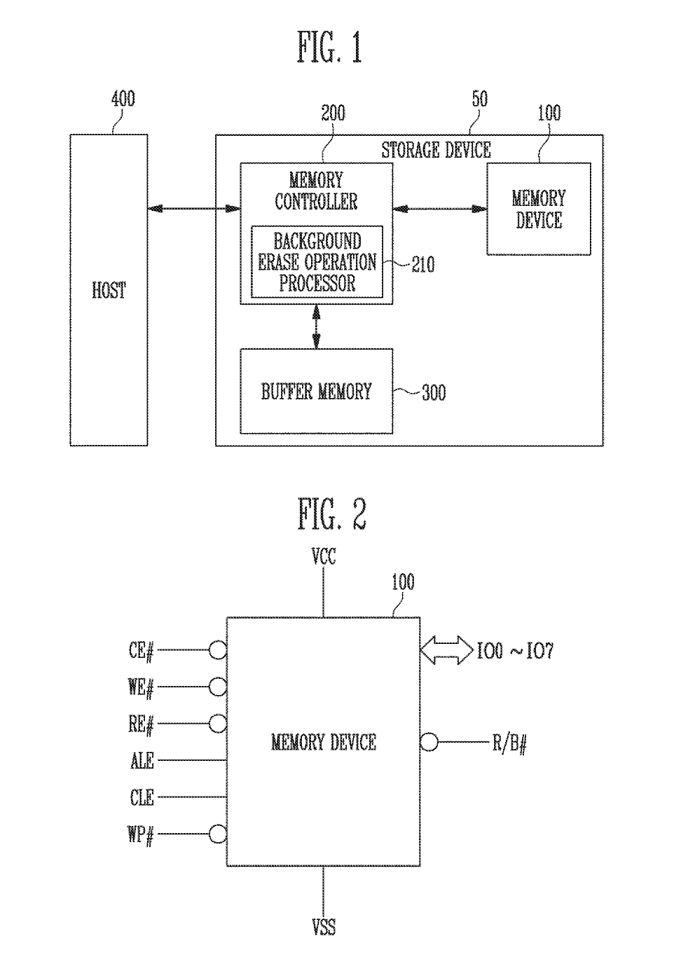

FIG. 1 is a block diagram illustrating a storage device 50 in accordance with an embodiment of the present disclosure.

Referring to FIG. 1, the storage device 50 may include a memory device 100 and a memory controller 200.

The storage device 50 may be a device configured to store data under control of a host 400. By way of example and not limitation, the host 400 may include devices such as a cellular phone, a smartphone, an MP3 player, a laptop computer, a desktop computer, a game machine, a TV, a tablet PC, or an in-vehicle infotainment system.

The storage device 50 may be configured of any one of various kinds of storage devices depending on a host interface, which is a communication system with the host 400. For example, the data storage device 300 may be configured of any one of various kinds of storage devices such as an SSD, MMC, eMMC, RS-MMC, or micro-MMC type multimedia card, an SD, mini-SD, micro-SD type secure digital card, a universal serial bus (USB) storage device, a universal flash storage (UFS) device, a personal computer memory card international association (PCMCIA) card type storage device, a peripheral component interconnection (PCI) card type storage device, a PCI-express (PCI-e or PCIe) type storage device, a compact flash (CF) card, a smart media card, and a memory stick.

The storage device 50 may be manufactured in the form of any one of various package types. For instance, the storage device 50 may be manufactured in the form of any one of various package types such as a package on package (POP) type, a system in package (SIP) type, a system on chip (SOC) type, a multi-chip package (MCP) type, a chip on board (COB) type, a wafer-level fabricated package (WFP) type, and a wafer-level stack package (WSP) type.

The memory device 100 may store data therein. The memory device 100 may operate under control of the memory controller 200. The memory device 100 may include a memory cell array including a plurality of memory cells configured to store data therein. The memory cell array may include a plurality of memory blocks. Each memory block may include a plurality of memory cells. Each memory block may include a plurality of pages. In an embodiment, each page may be the unit of sorting data in the memory device 100 or reading stored data from the memory device 100. The memory block may be the unit of erasing data.

The memory block may be classified into a free block or a data block depending on whether valid data is stored therein.

The free block may be an empty block in which no data is stored or a memory block in which invalid data is stored. The data block may be a block in which valid data is stored.

In an embodiment, the free block may be available to store data. Before data is stored in the free block, an erase operation may be performed on the free block to erase invalid data stored therein.

In an embodiment, the memory device 100 may be a double data rate synchronous dynamic random access memory (DDR SDRAM), a low power double data rate4 (LPDDR4) SDRAM, a graphics double data rate (GDDR) SDRAM, a low power DDR (LPDDR), a rambus dynamic random access memory (RDRAM), a NAND flash memory, a vertical NAND flash memory, a NOR flash memory device, a resistive random access memory (RRAM), a phase-change memory (PRAM), a magnetoresistive random access memory (MRAM), a ferroelectric random access memory (FRAM), or a spin transfer torque random access memory (STT-RAM). In this specification, for the sake of explanation, it is assumed that the memory device 100 is a NAND flash memory.

In an embodiment, the memory device 100 may be embodied in a two-dimensional or a three-dimensional array structure. The present disclosure may be applied not only to a flash memory in which a charge storage layer is formed of a conductive floating gate (FG), but also to a charge trap flash (CTF) memory in which a charge storage layer is formed of an insulating layer.

The memory device 100 may receive a command and an address from the memory controller 200, and access a region of the memory cell array that is selected by the address. In other words, the memory device 100 may perform an operation corresponding to the command on the region selected by the address. For example, the memory device 100 may perform a write (program) operation, a read operation, and an erase operation. During a program operation, the memory device 100 may program data to a region selected by an address. During a read operation, the memory device 100 may read data from a region selected by an address. During an erase operation, the memory device 100 may erase data from a region selected by an address.

The memory controller 200 may control the operation of the memory device 100 in response to a request of a host 400 or regardless of the request of the host 400.

For example, the memory controller 200 may control the memory device 100 to perform a program operation, a read operation, or an erase operation in response to a request from the host 400. During the program operation, the memory controller 200 may provide a program command, a physical address, and data to the memory device 100. During the read operation, the memory controller 200 may provide a read command and a physical address to the memory device 100. During the erase operation, the memory controller 200 may provide an erase command and a physical address to the memory device 100.

In an embodiment, the memory controller 200 may autonomously generate a program command, an address and data without a request from the host 400, and transmit them to the memory device 100. For example, the memory controller 200 may provide a command, an address and data to the memory device 100 so as to perform a program operation for wear leveling, or a program operation for garbage collection.

The memory controller 200 may execute firmware (FW) for controlling the memory device 100. When the memory device 100 is a flash memory device, the memory controller 200 may manage firmware such as a flash translation layer (FTL) for controlling communication between the host 400 and the memory device 100. In detail, the memory controller 200 may translate a logical address included in a request from the host 400 into a physical address.

In an embodiment of the present disclosure, the memory controller 200 may include a background erase operation processor 210. In an embodiment, the memory device 100 may perform a background erase operation under control of the memory controller 200. For example, the memory device 100 may receive a background erase command and an address from the memory controller 200. The memory device 100 may perform the background erase operation on a memory block corresponding to the address. The address provided along with the background erase command to the memory device 100 may be an address corresponding to any one free block among free blocks included in the memory device 100.

The background erase operation may be performed while the memory device 100 is in an idle state. The idle state may be a state in which the memory device 100 performs no operation. In an embodiment, the background erase operation may be performed until a confirm command indicating that transmission of data and an address relating to a normal operation command has been completed is inputted after the memory device 100 receives the normal operation command.

In an embodiment, the normal operation command may be a command indicating any one operation of a program operation, a read operation and an erase operation. For example, the normal operation command may be any one of a program command, a read command, and an erase command.

In an embodiment of the present disclosure, when the size of data to be stored in the memory device 100 exceeds the size of a memory block included in the memory device 100, the memory controller 200 may provide the memory device 100 with a background erase command instructing the memory device 100 to perform a background erase operation on at least one or more free blocks included in the memory device 100.

The memory device 100 may perform an erase operation on a free block in response to the background erase command while the memory device 100 is in an idle state. While the memory device 100 performs the background erase operation, the memory controller 200 may provide a command (CMD) instructing a normal operation to be performed, an address (ADD), and data (DATA) to the memory device 100.

If a normal operation command is inputted while the memory device 100 performs the background erase operation, the memory device 100 may perform the background erase operation until a confirm command corresponding to the normal operation command is inputted. If the confirm command inputted, the memory device 100 may suspend the background erase operation. In an embodiment, the memory device 100 may store background erase state information when the memory device 100 suspends the background erase operation. The memory device 100 may include a register (not shown) to store the background erase state information. The background erase state information may indicate the degree to which the suspended background erase operation has proceeded. For example, the background erase state information may indicate at least any one of the number of times an erase voltage pulse has been applied, the number of times an erase loop has been performed, a voltage level of the applied erase voltage pulse, and an erase verify result when the memory device 100 suspends the background erase operation.

The memory device 100 may keep the background erase operation suspended until performance of the normal operation command is completed. If the performance of the normal operation command is completed, the memory device 100 may resume the suspended background erase operation based on the stored background erase state information. For example, based on at least any one of the number of times the erase voltage pulse has been applied, the number of times the erase loop has been performed, the voltage level of the applied erase voltage pulse, and the erase verify result, the memory device 100 may resume the suspended background erase operation rather than performing the background erase operation from the beginning.

The memory controller 200 may include a buffer memory (not shown). In an embodiment, the memory controller 200 may control data exchange between the host 400 and the buffer memory. Alternatively, the memory controller 200 may temporarily store system data for controlling the memory device 100 to the buffer memory. For example, the memory controller 200 may temporarily store, in the buffer memory, data input from the host 400, and thereafter transmit the data temporarily stored in the buffer memory to the memory device 100.

In various embodiments, the buffer memory may be used as an operating memory or a cache memory of the memory controller 200. The buffer memory may store codes or commands to be executed by the memory controller 200. Alternatively, the buffer memory may store data to be processed by the memory controller 200. Furthermore, the buffer memory may store a logical-physical address mapping table indicating mapping relationship between logical addresses and physical addresses. By way of example and not limitation, the buffer memory device may be embodied using an SRAM or a DRAM such as a double data rate synchronous dynamic random access memory (DDR SDRAM), a DDR4 SDRAM, a low power double data rate4 (LPDDR4) SDRAM, a graphics double data rate (GDDR) SDRAM, a low power DDR (LPDDR), or a rambus dynamic random access memory (RDRAM). In various embodiments, the buffer memory may be included in the storage device 50 as a DRAM or an SRAM, rather than being included in the memory controller 200.

In an embodiment, the memory controller 200 may control at least two memory devices 100. In this case, the memory controller 200 may control the memory devices 100 in an interleaving manner so as to enhance the operating performance.

The host 400 may communicate with the storage device 50 using at least one of various communication methods such as universal serial bus (USB), serial AT attachment (SATA), serial attached SCSI (SAS), high speed interchip (HSIC), small computer system interface (SCSI), peripheral component interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

The storage device 50 may be configured of any one of various kinds of storage devices depending on a host interface, which is a communication system with the host 400. For example, the storage device 50 may be configured of any one of various kinds of storage devices such as an SSD, MMC, eMMC, RS-MMC, or micro-MMC type multimedia card, an SD, mini-SD, micro-SD type secure digital card, a universal serial bus (USB) storage device, a universal flash storage (UFS) device, a personal computer memory card international association (PCMCIA) card type storage device, a peripheral component interconnection (PCI) card type storage device, a PCI-express (PCI-e or PCIe) type storage device, a compact flash (CF) card, a smart media card, and a memory stick.

The storage device 50 may be manufactured in the form of any one of various package types. For instance, the storage device 50 may be manufactured in the form of any one of various package types such as a package on package (POP) type, a system in package (SIP) type, a system on chip (SOC) type, a multi-chip package (MCP) type, a chip on board (COB) type, a wafer-level fabricated package (WFP) type, and a wafer-level stack package (WSP) type.

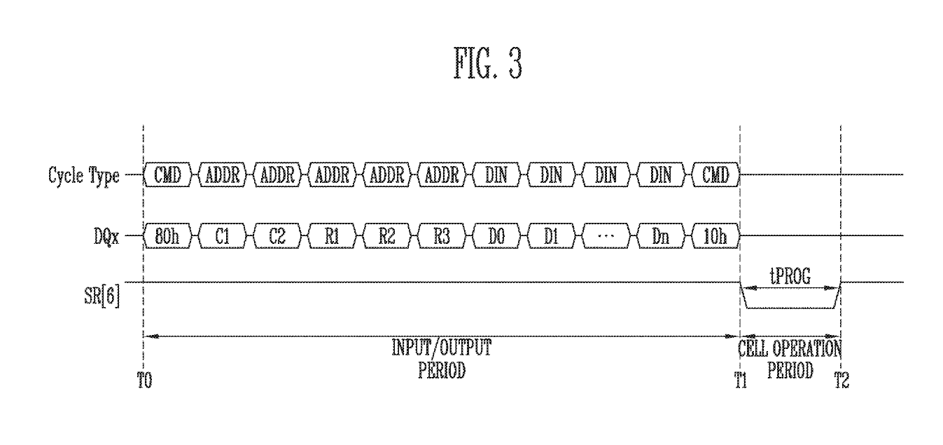

FIG. 2 is a diagram describing signals which are inputted to or outputted from the memory device 100 of FIG. 1.

Referring to FIG. 2, the memory device 100 may communicate with an external controller through a plurality of input/output lines. For example, the memory device 100 may communicate with the external controller through data input/output lines IO0 to IO7, and control signal lines including a chip enable line CE#, a write enable line WE#, a read enable line RE#, an address latch enable linen ALE, a command latch enable line CLE, a write inhibit line WP#, and a ready/busy line R/B#.

The memory device 100 may receive a chip enable signal from the external controller through the chip enable line CE#. The memory device 100 may receive a write enable signal from the external controller through the write enable line WE#. The memory device 100 may receive a read enable signal from the external controller through the read enable line RE#. The memory device 100 may receive an address latch enable signal from the external controller through the address latch enable line ALE. The memory device 100 may receive a command latch enable signal from the external controller through the command latch enable line CLE. The memory device 100 may receive a write inhibit signal from the external controller through the write inhibit line WP#.

In an embodiment, the memory device 100 may output a read/busy signal indicating whether the memory device 100 is in a ready state or a busy state, to the memory controller 200 through the ready/busy line R/B#.

The chip enable signal may be a control signal for selecting the memory device 100. If the chip enable signal is a “high” state and the memory device 100 corresponds to a “ready” state, the memory device 100 may enter a low power standby state.

The write enable signal may be a control signal for controlling an operation of storing, in a latch, a command, an address, and input data to be inputted to the memory device 100.

The read enable signal may be a control signal for enabling output of serial data.

The address latch enable signal may be one of control signals to be used by the host to indicate whether the type of signal to be inputted to the input/output lines IO0 to IO7 is a command, an address or data.

The command latch enable signal may be one of control signals to be used by the host to indicate whether the type of signal to be inputted to the input/output lines IO0 to IO7 is a command, an address or data.

For example, if the command latch enable signal is enabled (e. g., to a logic high level), the address latch enable signal is disabled (e.g., to a logic low level), and the write enable signal is enabled (e.g., to a logic low level) and thereafter disabled (e.g., to a logic high level), the memory device 100 may recognize that the signal inputted through the input/output lines IO0 to IO07 is a command.

For example, if the command latch enable signal is disabled (e. g., to a logic low level), the address latch enable signal is enabled (e.g., to a logic high level), and the write enable signal is enabled (e.g., to the logic low level) and thereafter disabled (e.g., to the logic high level), the memory device 100 may recognize that the signal inputted through the input/output lines IO0 to IO07 is an address.

The write inhibit signal may be a control signal for inhibiting the memory device 100 from performing a program operation or an erase operation.

The ready/busy signal may a signal for indicating the state of the memory device 100. A ready/busy signal having a low state may indicate that the memory device 100 is performing at least one operation. A read busy signal having a high state may indicate that the memory device 100 is performing no operation.

While the memory device 100 performs any one of a program operation, a read operation, and an erase operation, the ready/busy signal may be in a low state. In an embodiment of the present disclosure, while the memory device 100 performs a background erase operation described with reference to FIG. 1, the ready/busy signal may be in a high state. Therefore, while the memory device 100 performs a background erase operation, the memory device 100 may receive, through the input/output lines IO0 to IO7, a command, an address, and data that correspond to a normal operation and are provided from the memory controller 200.

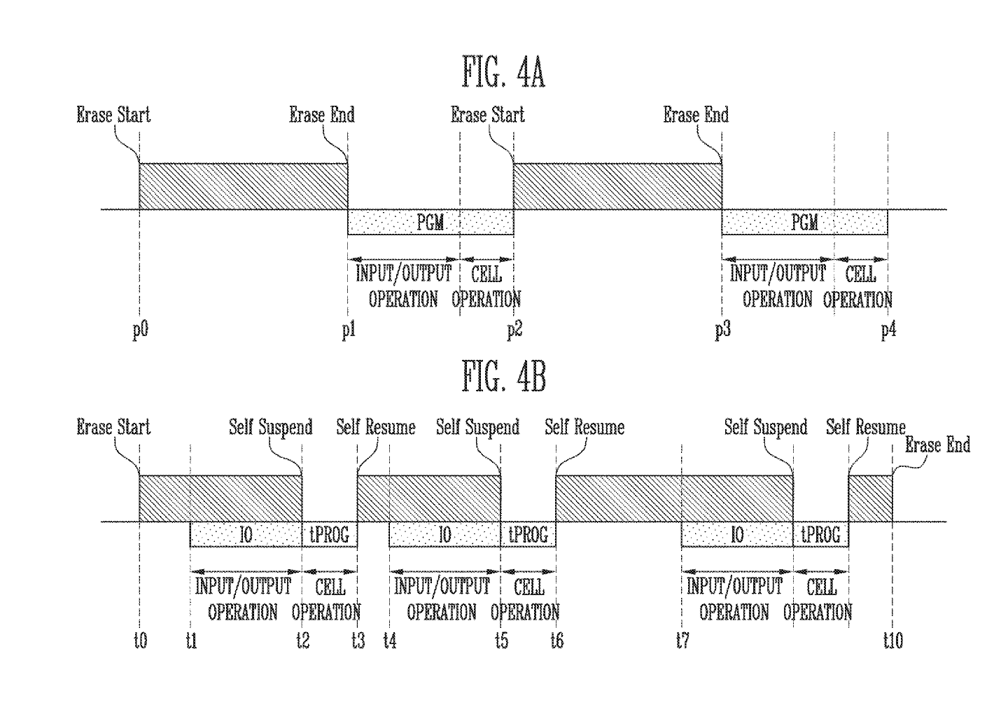

FIG. 3 is a diagram for describing an input/output operation and a cell operation of the memory device 100 during a program operation in accordance with an embodiment of the present disclosure.

In an embodiment of the present disclosure, the memory controller 200 may control the memory device 100 to perform a background erase operation depending on the size of write data which is data to be stored in the memory device 100. The background erase operation may be used as a method of efficiently performing an erase operation which requires a comparatively long time.

The memory device 100 may erase at least one or more selected memory blocks through a background erase operation in response to a background erase command provided form the memory controller 200. In an embodiment, the memory device 100 may receive a normal operation command while the background erase operation is performed. In an embodiment, the normal operation command may be a program command. In various embodiments, the normal operation command may be a read command or an erase command.

The normal operation command may include a first command and a second command. The first command may be a start command indicating the type of normal operation. The second command may be a confirm command indicating that an address and data needed to perform the first command have been completely inputted. Even when the first command of the normal operation command is inputted while a background erase operation is performed, the memory device 100 may perform the background erase operation until the confirm command which is the second command of the normal operation command is inputted.

Hereinafter, a case where the normal operation command is a program command will be described by way of example. However, embodiments of the present disclosure are not limited to the case where the normal operation command is a program command. That is, the normal operation command may be a read command or an erase command depending on an embodiment.

Referring to FIG. 3, “DQx” may indicate signals to be inputted through the input/output lines IO0 to IO7 described with reference to FIG. 2, and “Cycle Type” may indicate the types of corresponding signals. “SR[6]” may indicate a ready/busy signal to be outputted through the ready/busy line R/B# described with reference to FIG. 2. In an embodiment, “SR[6]” may indicate the value of a state register included in the memory device 100. The state register may store state information indicating whether the memory device 100 has completed performance of a received normal operation command or background erase operation command.

During a period from T0 to T1, the memory device 100 may receive a program command, an address, and data.

The program command may be a first command of a program command. For example, the program command may be a start command of the program operation.

During a period from T1 to T2, the memory device 100 may perform the program operation of programming data to a region corresponding to the received address. In detail, the memory device 100 may receive 80h indicating a program command CMD at time T0. Thereafter, during five cycles, the memory device 100 may receive addresses ADDR. The inputted addresses ADDR may include column addresses C1 and C2 and row addresses R1, R2, and R3.

Subsequently, the memory device 100 may receive program data D0 to Dn which are data to be programmed. After the program data D0 to Dn have been inputted, the memory device 100 may receive a second command 10h. The second command 10h may be a confirm command indicating that the program command CMD (80h), which is the first command, the associated addresses (C1, C2, R1, R2, R3), and data (D0 to Dn) have been completely inputted.

If the second command 10h is inputted, the memory device 100 may perform a program operation of storing the inputted program data D0 to Dn in regions corresponding to the inputted addresses ADDR. The memory device 100 may perform the program operation during a period tPROG from T1 to T2.

As such, during the period from T0 to T1, the memory device 100 may perform an input/output operation of receiving, through the input/output lines IO0 to IO7, the commands CMD, the addresses ADDR, and the data D0 to Dn that are needed to perform the program operation. After the confirm command has been inputted, during the period from T1 to T2, the memory device 100 may perform a cell operation of performing the program operation of storing the program data D0 to Dn in the regions corresponding to the addresses ADDR.

In other words, during the period from T0 to T1, the memory device 100 may only receive, through the input/output lines IO0 to IO7, the commands CMD, the addresses ADDR, and the data D0 to Dn that are needed to perform the program operation, without performing the program operation of actually storing the data in memory cells. Therefore, while the input/output operation corresponding to the period from T0 to T1 is performed, other operations may be performed on the memory cells.

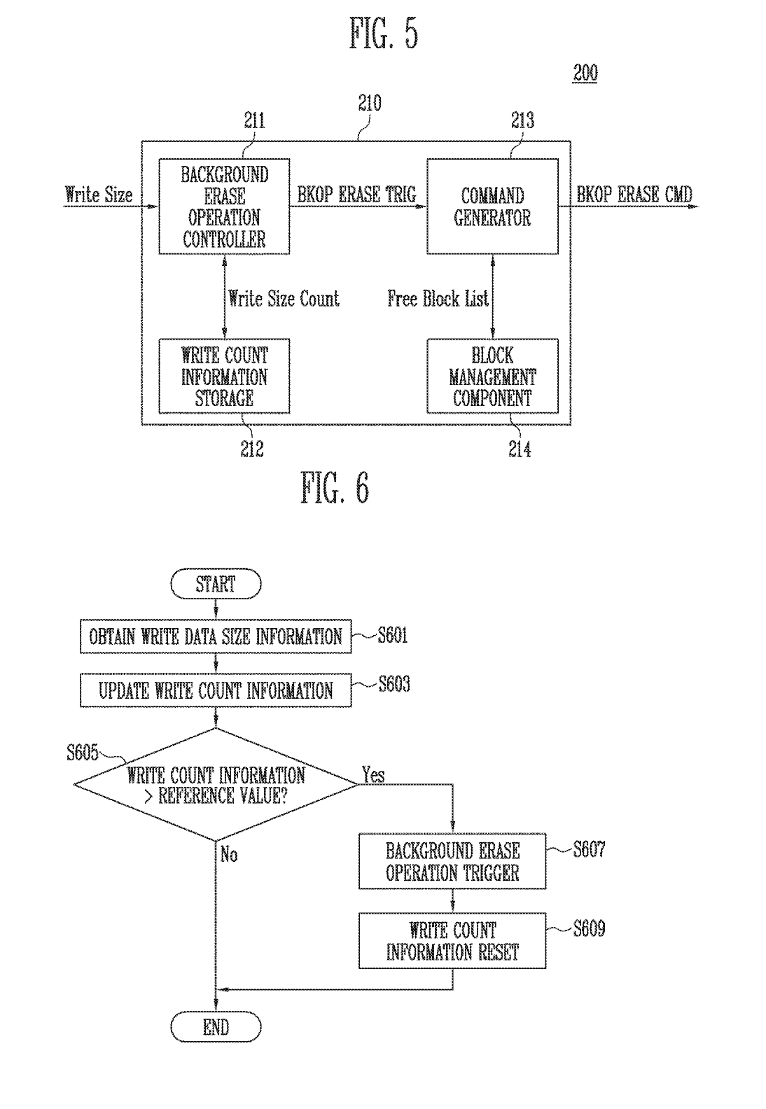

FIG. 4A and FIG. 4B describe a background erase operation in accordance with an embodiment of the present disclosure.

FIG. 4A is a diagram illustrating the case where a program command is inputted while a normal (i.e., foreground) erase operation is performed. FIG. 4B is a diagram illustrating the case where a program command is inputted while a background erase operation is performed, in accordance with an embodiment of the present disclosure.

Referring to FIG. 4A, a normal erase operation may be performed during a period from p0 to p1. Time p0 may be a time at which the normal erase operation starts. Time p1 may be a time at which the normal erase operation is completed. During the period from p0 to p1, a busy signal may be outputted through the ready/busy line of the memory device 100. Therefore, the memory device 100 may not receive a subsequent command which may be a program command. After the normal erase operation has been completed, the memory device 100 may receive a subsequent program command for instructing the program operation to be performed, an address, and data from the memory controller 200, and may perform the program operation of storing the inputted data in a selected region corresponding to the address.

A period from p1 to p2 during which the program operation (denoted as PGM in FIG. 4A) is performed may be divided into an input/output operation period in which the memory device 100 receives a first command, the address, the data, and a second command from the memory controller 200, and a cell operation period in which the inputted data is stored in memory cells selected by the address. In an embodiment, the first command may be a start command indicating that the inputted command pertains to the program operation. For example, the start command may be a program command. In an embodiment, the second command may be a confirm command indicating that the input of the address and the data needed to perform the first command has been completed.

During a period from p2 to p3, an normal erase operation may be performed. Time p2 may be a time at which the normal erase operation starts. Time p3 may be a time at which the normal erase operation is completed. During the period from p2 to p3, a busy signal may be being outputted through the ready/busy line of the memory device 100. Therefore, the memory device 100 may not receive a subsequent command which may be a program command. After the normal erase operation has been completed, the memory device 100 may receive a subsequent program command for instructing the program operation to be performed, an address, and data from the memory controller 200, and may perform the program operation of storing the inputted data in a selected region corresponding to the address.

A period from p3 to p4 during which the program operation is performed may be divided into an input/output operation period in which the memory device 100 receives a first command, the address, the data, and a second command from the memory controller 200, and a cell operation period in which the inputted data is stored in memory cells selected by the address. In an embodiment, the first command may be a start command indicating that the inputted command pertains to the program operation. For example, the start command may be a program command. In an embodiment, the second command may be a confirm command indicating that the input of the address and the data needed to perform the first command has been completed.

As shown in FIG. 4A, while a normal erase operation is performed, the memory device 100 may not receive subsequent normal operation commands. Therefore, despite the fact that input/output data paths other than the memory cell region are not actually operated, only after the normal erase operation has been completed can other normal operations be performed.

Referring to FIG. 4B, time t0 may be a time at which a background erase operation starts. While the background erase operation is performed, the memory device 100 may receive a normal operation command from the memory controller 200.

At time t1, the memory device 100 may receive a normal command pertaining to a program operation. In detail, the memory device 100 may receive a first command, an address, data, and a second command during a period from t1 to t2. In an embodiment, the first command may be a start command indicating the program operation. The second command may be a confirm command indicating that the input of the address and the data needed to perform the first command has been completed.

When the confirm command is inputted at time t2, the memory device 100 itself may suspend the ongoing background erase operation even though no separate suspend command is received, as indicated with “Self Suspend” in FIG. 4B. In other words, when the confirm command of the normal operation command is inputted, the memory device 100 may suspend the ongoing background erase operation, in response to the inputted confirm command. The memory device 100 may suspend the background erase operation, and then store background erase state information on the suspended background erase operation. In an embodiment, the background erase status information may indicate the degree to which the suspended background erase operation has proceeded. For example, the background erase status information may indicate at least any one of the number of times an erase voltage pulse has been applied, the number of times an erase loop has been performed, a voltage level of the applied erase voltage pulse, and an erase verify result when the memory device 100 suspends the background erase operation.

During a period from t2 to t3, the memory device 100 may perform a program operation (denoted as tPROG in FIG. 43) in response to the program command inputted during the period from t1 to t2.

When the program operation is completed at time t3, the memory device 100 may resume the background erase operation suspended at time t2. Here, even though an operation resume command is not received from the memory controller 200, the memory controller 200 itself may resume the suspended background erase operation in response to a state information value indicating that the program operation has been completed, as indicated with “Self Resume” in FIG. 4B. When the suspended background erase operation is resumed, the memory device 100 may resume the background erase operation based on the background erase state information stored at time t2. For example, the memory device 100 may resume the suspended background erase operation based on at least one of the number of times the erase voltage pulse has been applied, the number of times the erase loop has been performed, the voltage level of the applied erase voltage pulse, and the erase verify result at time t2 at which the background erase operation is suspended.

At time t4, the memory device 100 may receive a normal command pertaining to a program operation. In detail, the memory device 100 may receive a first command, an address, data, and a second command during a period from t4 to t5. In an embodiment, the first command may be a start command indicating the program operation. The second command may be a confirm command indicating that the input of the address and the data needed to perform the first command has been completed.

When the confirm command is inputted at time t5, the memory device 100 itself may re-suspend the ongoing background erase operation even though no separate suspend command is received (denoted as “Self Suspend”). In other words, when the confirm command of the normal operation command is inputted, the memory device 100 may suspend the ongoing background erase operation, in response to the inputted confirm command. The memory device 100 may suspend the background erase operation, and then store background erase state information on the suspended background erase operation. In an embodiment, the background erase status information may indicate the degree to which the background erase operation has proceeded. For example, the background erase status information may indicate at least any one of the number of times an erase voltage pulse has been applied, the number of times an erase loop has been performed, a voltage level of the applied erase voltage pulse, and an erase verify result when the memory device 100 suspends the background erase operation.

During a period from t5 to t6, the memory device 100 may perform a program operation in response to the program command inputted during the period from t4 to t5.

When the program operation is completed at time t6, the memory device 100 may resume the background erase operation suspended at time t5. Here, even though an operation resume command is not received from the memory controller 200, the memory controller 200 itself may resume the suspended background erase operation in response to a state information value indicating that the program operation has been completed (denoted as “Self Resume”). When the suspended background erase operation is resumed, the memory device 100 may resume the background erase operation based on the background erase state information stored at time t5. For example, the memory device 100 may resume the suspended background erase operation based on at least one of the number of times the erase voltage pulse has been applied, the number of times the erase loop has been performed, the voltage level of the applied erase voltage pulse, and the erase verify result at time t5 at which the background erase operation is suspended.

At time t7, the memory device 100 may receive a normal command pertaining to a program operation. In detail, the memory device 100 may receive a first command, an address, data, and a second command during a period from t7 to t8. In an embodiment, the first command may be a start command indicating the program operation. The second command may be a confirm command indicating that the input of the address and the data needed to perform the first command has been completed.

When the confirm command is inputted at time t8, the memory device 100 itself may re-suspend the ongoing background erase operation even though no separate suspend command is received (denoted as “Self Suspend”). In other words, when the confirm command of the normal operation command is inputted, the memory device 100 may suspend the ongoing background erase operation, in response to the inputted confirm command. The memory device 100 may suspend the background erase operation, and then store background erase state information on the suspended background erase operation. In an embodiment, the background erase status information may indicate the degree to which the background erase operation has proceeded. For example, the background erase status information may indicate at least any one of the number of times an erase voltage pulse has been applied, the number of times an erase loop has been performed, a voltage level of the applied erase voltage pulse, and an erase verify result when the memory device 100 suspends the background erase operation.

During a period from t8 to t9, the memory device 100 may perform a program operation in response to the program command inputted during the period from t7 to t8.

When the program operation is completed at time t9, the memory device 100 may resume the background erase operation suspended at time t8. Here, even though an operation resume command is not received from the memory controller 200, the memory controller 200 itself may resume the suspended background erase operation in response to a state information value indicating that the program operation has been completed (denoted as “Self Resume”). When the suspended background erase operation is resumed, the memory device 100 may resume the background erase operation based on the background erase state information stored at time t8. For example, the memory device 100 may resume the suspended background erase operation based on at least one of the number of times the erase voltage pulse has been applied, the number of times the erase loop has been performed, the voltage level of the applied erase voltage pulse, and the erase verify result at time t8 at which the background erase operation is suspended.

At time t10, the background erase operation that has been performed by the memory device 100 may be terminated.

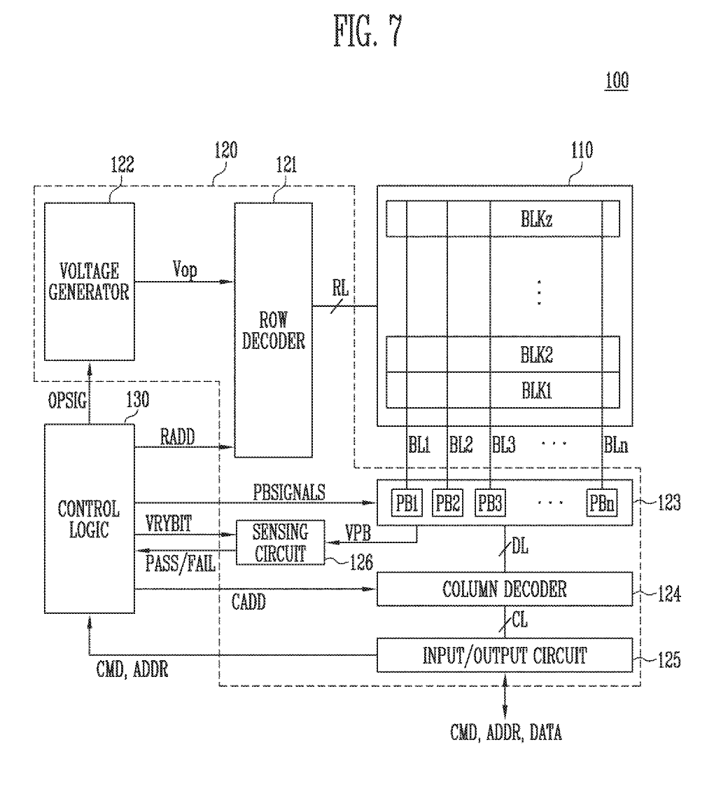

FIG. 5 is a block diagram illustrating a configuration of the memory controller 200 of FIG. 1 in accordance with an embodiment of the present disclosure.

The memory controller 200 may include the background erase operation processor 210 as described with reference to FIG. 1. The background erase operation processor 210 may control the memory device 100 to perform a background erase operation on at least one or more free blocks depending on the size of data to be stored in the memory device 100.

Referring to FIG. 5, the background erase operation processor 210 may include a background erase operation controller 211, a write count information storage 212, a command generator 213, and a block management component 214.

The background erase operation controller 211 may provide triggering information BKOP ERASE TRIG indicating a start of a background erase operation to the command generator 213.

In detail, the background erase operation controller 211 may receive, from the memory controller 200, write data size information Write Size which is information about the size of data to be stored in the memory device 100. The background erase operation controller 211 may store the write data size information Write Size as write count information Write Size Count in the write count information storage 212. Each time the memory controller 200 stores data in the memory device 100, the background erase operation controller 211 may receive write data size information Write Size, and update the write count information Write Size Count in the write count information storage 212. For example, each time the memory controller 200 transmits, to the memory device 100, a program command instructing the memory device 100 to store data, the background erase operation controller 211 may receive write data size information Write Size. The background erase operation controller 211 may store and update the write count information Write Size Count in the write count information storage 212 by accumulating the write data size information Write Size into the write count information Write Size Count whenever the background erase operation controller 211 receives the write data size information Write Size.

The background erase operation controller 211 may determine whether the write count information Write Size Count exceeds a preset reference value. In an embodiment, the preset reference value may be a value corresponding to a storage capability of a memory block included in the memory device 100. In other words, the background erase operation controller 211 may determine whether the write count information Write Size Count exceeds the storage capability of a single memory block.

The write count information Write Size Count exceeding a storage capability of a single memory block means data having the greater size than the storage capability of a single memory block has been stored in the memory device 100 and thus more storage space is required to be secured in advance for future data storage. If data is stored in a memory block included in the memory device 100, the memory controller 200 may allocate at least one or more free blocks among a plurality of free blocks included in the memory device 100, and subsequently store data in the allocated memory blocks. Therefore, if write count information Write Size Count which is a value obtained by accumulating write data size information Write Size which is information about the size of data already stored in the memory device 100 exceeds a storage capacity of a single memory block, a new memory block should be secured such that it is allocated for storing data.

If the write count information Write Size Count exceeds a storage capacity a single memory block, the background erase operation controller 211 may provide triggering information BKOP ERASE TRIG indicating a start of a background erase operation to the command generator 213 so that the background erase operation starts to be performed on at least one free block.

When providing the triggering information BKOP ERASE TRIG, the background erase operation controller 211 may reset the write count information Write Size Count in the background erase operation controller 211.

The command generator 213 may receive the triggering information BKOP ERASE TRIG indicating the start of the background erase operation from the background erase operation controller 211. When the triggering information BKOP ERASE TRIG is received, the command generator 213 may generate a background erase operation command BKOP ERASE CMD instructing at least one free block included in a free block list stored in the block management component 214 to be erased. The command generator 213 may provide the generated background erase operation command BKOP ERASE CMD to the memory device 100.

The block management component 214 may store the free block list. The free block list may include address information of the free blocks. In an embodiment, the free block list may be a list in which the addresses of the free blocks are stored in a sequence from lowest to highest in the erase operation count. Hence, the memory controller 200 may first erase free blocks having comparatively low erase operation counts, whereby the erase operation counts of the memory blocks may be uniformly managed.

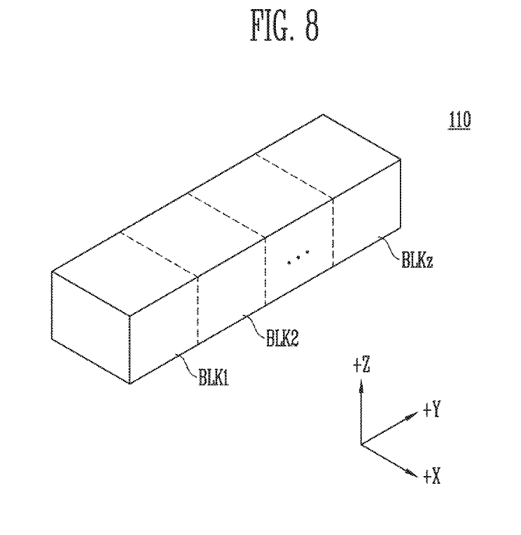

FIG. 6 is a flowchart describing a method of operating the memory controller 200 in accordance with an embodiment of the present disclosure.

At step S601, the memory controller 200 may obtain write data size information. In detail, the memory controller 200 may obtain write data size information which is information about the size of data to be the memory device 100.

At step S603, the memory controller 200 may update write count information by accumulating the write data size information.

At step S605, the memory controller 200 may determine whether the write count information exceeds a preset reference value. In an embodiment, the reference value may represent the storage capacity of a single memory block.

When the memory controller 200 determines that the write count information does not exceed a preset reference value (that is, “No” at step S605), the operation of the memory controller 200 may end.

When the memory controller 200 determines that the write count information exceeds a preset reference value (that is, “Yes” at step S605), the memory controller 200 may trigger a background erase operation, at step S607. Then, at step S609, the memory controller 200 may reset the write count information.

In various embodiments of the present disclosure, if the memory device 100 stores data corresponding to the capacity of a single memory block (i.e., if a single memory block is consumed), the memory controller 200 may provide a background erase operation command to the memory device 100 to erase a new free block. Thereby, the memory controller 200 may prevent a write operation to be subsequently performed from being delayed by the operation of erasing the memory block.

FIG. 7 is a diagram illustrating the configuration of the memory device 100 of FIG. 1.

Referring to FIG. 7, the memory device 100 may include a memory cell array 110, a peripheral circuit 120, and a control logic 130.

The memory cell array 110 may include a plurality of memory blocks BLK1 to BLKz. The plurality of memory blocks BLK1 to BLKz are coupled to a row decoder 121 through row lines RL. The plurality of memory blocks BLK1 to BLKz may be coupled to a page buffer group 123 through bit lines BL1 to BLm. Each of the memory blocks BLK1 to BLKz may include a plurality of memory cells. In an embodiment, the plurality of memory cells may be nonvolatile memory cells. Memory cells coupled to the same word line may be defined as one page. Hence, each memory block may include a plurality of pages.

The row lines RL may include at least one source select line, a plurality of word lines, and at least one drain select line.

Each of the memory cells included in the memory cell array 110 may be formed of a single level cell (SLC) capable of storing a single data bit, a multi-level cell (MLC) capable of storing two data bits, a triple-level cell (TLC) capable of storing three data bits, or a quad-level cell (QLC) capable of storing four data bits.

The peripheral circuit 120 may perform a program operation, a read operation, or an erase operation on a selected region of the memory cell array 110 under control of the control logic 130. The peripheral circuit 120 may drive the memory cell array 110. For example, the peripheral circuit 120 may apply various operating voltages to the row liens RL and the bit lines BL1 to BLn or discharge the applied voltages, under control of the control logic 130.

The peripheral circuit 120 may include the row decoder 121, a voltage generator 122, the page buffer group 123, a column decoder 124, and an input/output circuit 125.

The row decoder 121 is coupled to the memory cell array 110 through the row lines RL. The row lines RL may include at least one source select line, a plurality of word lines, and at least one drain select line. In an embodiment, the word lines may include normal word lines and dummy word lines. In an embodiment, the row lines RL may further include a pipe select line.

The row decoder 121 may operate under control of the control logic 130. The row decoder 121 may receive a row address ADDR from the control logic 130.

The row decoder 121 may decode the row address RADD. The row decoder 121 may select at least one memory block of the memory blocks BLK1 to BLKz in response to the decoded address. The row decoder 121 may select at least one word line WL of the selected memory block in response to the decoded address so that voltages generated from the voltage generator 122 are applied to the at least one word line WL.

For example, during a program operation, the row decoder 121 may apply a program voltage to a selected word line and apply a program pass voltage having a level lower than that of the program voltage to unselected word lines. During a program verify operation, the row decoder 121 may apply a verify voltage to a selected word line and apply a verify pass voltage higher than the verify voltage to unselected word lines. During a read operation, the row decoder 121 may apply a read voltage to a selected word line and apply a read pass voltage higher than the read voltage to unselected word lines.

In an embodiment, an erase operation of the memory device 100 may be performed on a memory block basis. During an erase operation, the row decoder 121 may select one memory block in response to a decoded address. During the erase operation, the row decoder 121 may apply a ground voltage to word lines coupled to the selected memory block.

The voltage generator 122 may operate under control of the control logic 130. The voltage generator 122 may generate a plurality of voltages using an external supply voltage supplied to the memory device 100. In detail, the voltage generator 122 may generate various operating voltages Vop to be used for a program operation, a read operation, and an erase operation in response to an operating signal OPSIG. For example, the voltage generator 122 may generate a program voltage, a verify voltage, a pass voltage, a read voltage, an erase voltage, and so forth under control of the control logic 130.

In an embodiment, the voltage generator 122 may generate an internal supply voltage by regulating the external supply voltage. The internal supply voltage generated from the voltage generator 122 may be used as an operating voltage of the memory device 100.

In an embodiment, the voltage generator 122 may generate a plurality of voltages using an external supply voltage or an internal supply voltage.

For example, the voltage generator 122 may include a plurality of pumping capacitors for receiving the internal supply voltage and generate a plurality of voltages by selectively activating the plurality of pumping capacitors under control of the control logic 130.

The generated voltages may be supplied to the memory cell array 110 by the row decoder 121.

The page buffer group 230 may include first to n-th page buffers PB1 to PBn. The first to n-th page buffers PB1 to PBn are coupled to the memory cell array 110 through the first to n-th bit lines BL1 to BLn, respectively. The first to n-th page buffers PB1 to PBn may operate under control of the control logic 130. In detail, the first to n-th page buffers PB1 to PBn may operate in response to page buffer control signals PBSIGNALS. For instance, the first to n-th page buffers PB1 to PBn may temporarily store data received through the first to n-th bit lines BL1 to BLn, or sense voltages or currents of the first to n-th bit lines BL1 to BLn during a read operation or a verify operation.

In detail, during a program operation, the first to n-th page buffers PB1 to PBn may transmit data DATA received through the input/output circuit 125 to selected memory cells through the first to n-th bit lines BL1 to BLn when a program pulse is applied to a selected word line. The memory cells in the selected page are programmed based on the transmitted data DATA. Memory cells coupled to a bit line to which a program allowable voltage (e.g. a ground voltage) is applied may have increased threshold voltages. Threshold voltages of memory cells coupled to a bit line to which a program inhibit voltage (for example, a supply voltage) is applied may be retained. During a program verify operation, the first to n-th page buffers PB1 to PBn may read page data from selected memory cells through the first to n-th bit lines BL1 to BLn.

During a read operation, the first to n-th page buffers PB1 to PBn may read data DATA from memory cells of a selected page through the first to n-th bit lines BL1 to BLn, and output the read data DATA to the data input/output circuit 125 under control of the column decoder 124.

During an erase operation, the first to n-th page buffers PB1 to PBn may float the first to n-th bit lines BL1 to BLn.

The column decoder 124 may transmit data between the input/output circuit 125 and the page buffer group 123 in response to a column address CADD. For example, the column decoder 124 may exchange data with the first to n-th page buffers PB1 to PBn through data lines DL or exchange data with the input/output circuit 125 through column lines CL.

The input/output circuit 125 may transmit, to the control logic 130, a command CMD or an address ADDR received from the memory controller 200 described with reference to FIG. 1, or may exchange data DATA with the column decoder 124.

During a read operation or a verify operation, the sensing circuit 126 may generate a reference current in response to an allowable bit signal VRYBIT, and may compare a sensing voltage VPB received from the page buffer group 123 with a reference voltage generated by the reference current and output a pass signal PASS or a fail signal FAIL.

The control logic 130 may output an operating signal OPSIG, a row address RADD, page buffer control signals PBSIGNALS, and an allowable bit signal VRYBIT in response to a command CMD and an address ADD, and thus control the peripheral circuit 120. In addition, the control logic 130 may determine whether a target memory cell has passed or failed a verify operation in response to a pass or fail signal PASS or FAIL.

In an embodiment, the control logic 130 may control the peripheral circuit 120 to process a background erase operation.

The background erase operation may be an erase operation to be performed while the memory device 100 is in an idle status. The idle status may be a status in which the memory device 100 does not perform an operation. In an embodiment, the background erase operation may be an erase operation which is performed until a confirm command indicating that transmission of data and an address related to a normal operation command has been completed is inputted after the memory device 100 receives the normal operation command.

In an embodiment, the normal operation command may be a command indicating any one operation of a program operation, a read operation and an erase operation. For example, the normal operation command may be any one of a program command, a read command, and an erase command.

In detail, the control logic 130 may determine whether a command CMD inputted from the memory controller 200 is a background erase command. If a background erase command is inputted, the control logic 130 may perform an erase operation on a memory block corresponding to the background erase command while the memory device 100 is in an idle state. While the background erase command is performed, the memory device 100 may receive a command CMD, an address ADDR, and data DATA.

If a normal operation command is inputted while the background erase operation is performed, the control logic 130 may perform the background erase operation until a confirm command corresponding to the normal operation command is inputted. If the confirm command is inputted, the control logic 130 may suspend the background erase operation, and store background erase state information. The background erase status information may indicate the degree to which the background erase operation has proceeded. For example, the background erase status information may indicate at least any one of the number of times an erase voltage pulse has been applied, the number of times an erase loop has been performed, a voltage level of the applied erase voltage pulse, and an erase verify result.

The control logic 130 may suspend the performance of the background erase operation until performance of the normal operation command is completed. If the performance of the normal operation command is completed, the control logic 130 may resume the suspended background erase operation based on the stored background erase state information. For example, based on at least any one of the number of times the erase voltage pulse has been applied, the number of times the erase loop has been performed, the voltage level of the applied erase voltage pulse, and the erase verify result, the control logic 130 may resume the background erase operation from a suspended state on the memory block on which the suspended background erased operation has been performed, rather than performing the erase operation from the beginning.

In various embodiments, the control logic 130 may determine whether the normal operation command inputted while the background erase operation is performed is an erase operation pertaining to the memory block on which the background erase operation is being performed. If the inputted normal operation command pertains to an erase operation for the memory block on which the background erase operation is being performed, the control logic 130 may perform the erase operation on the corresponding memory block in succession from the point at which the background erase operation is suspended, based on the background erase state information, rather than performing the erase operation on the corresponding memory block from the beginning.

FIG. 8 is a diagram illustrating an embodiment of the memory cell array 110 of FIG. 7.

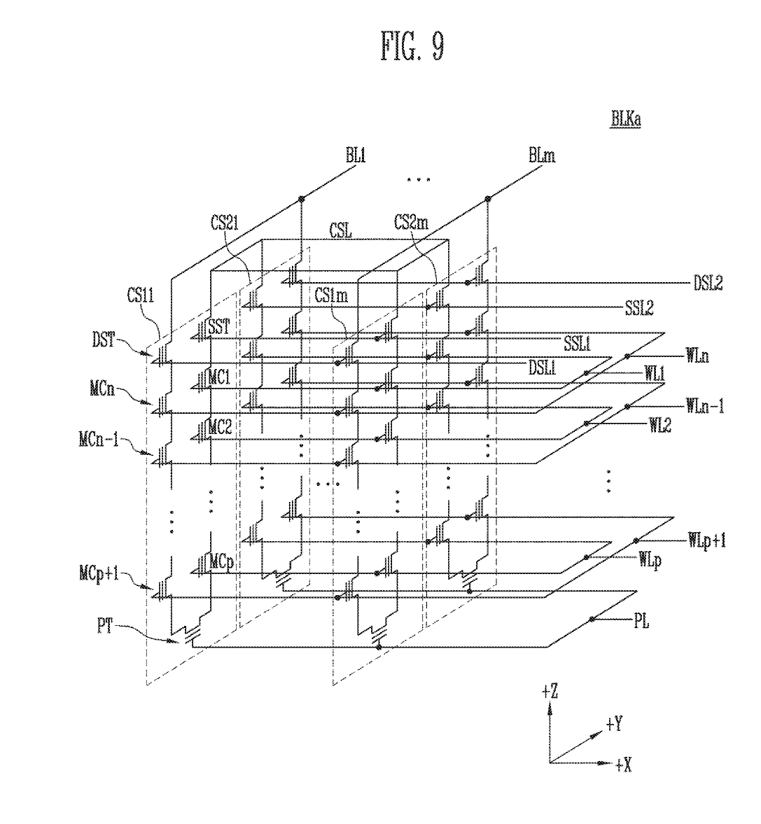

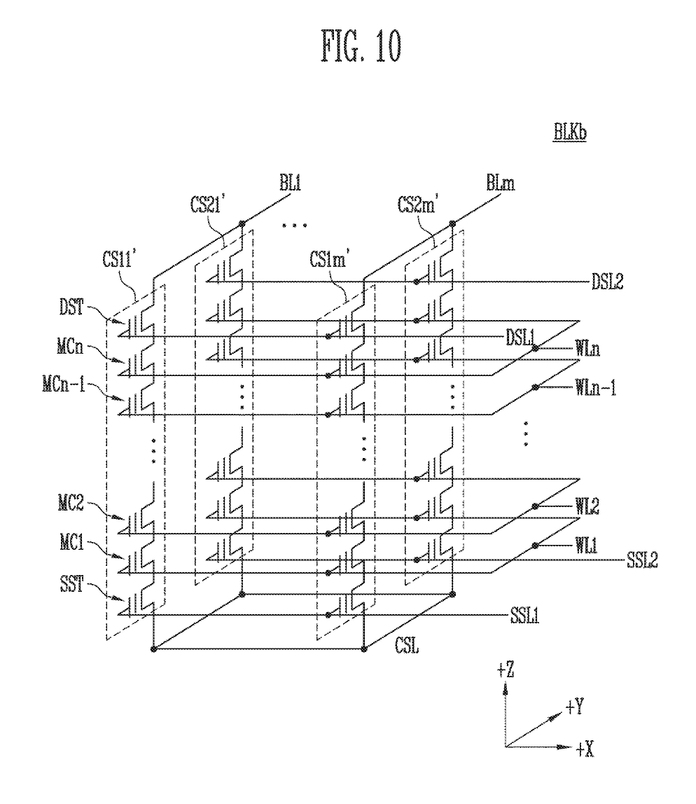

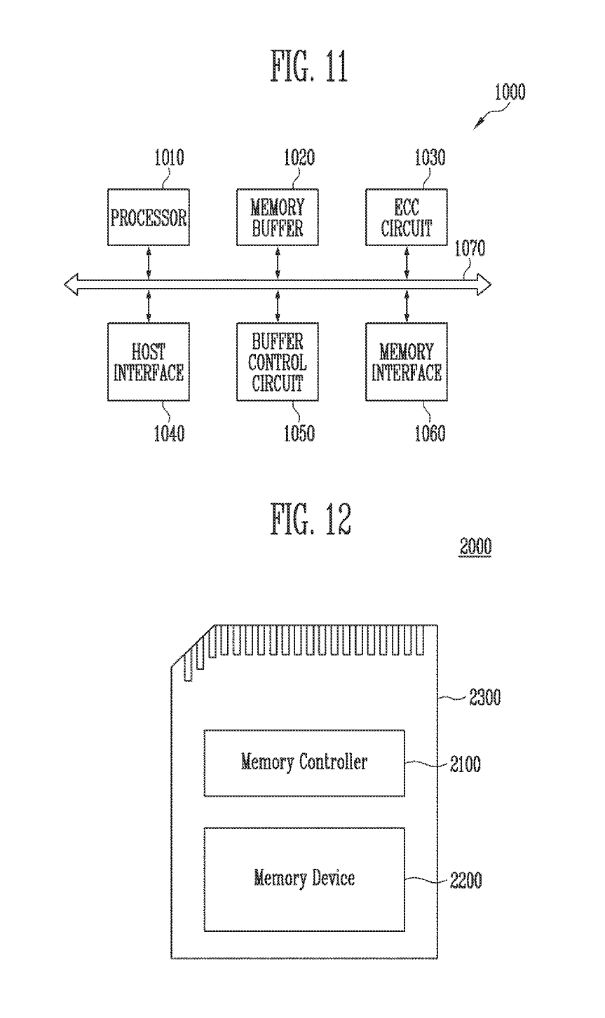

Referring to FIG. 8, the memory cell array 110 may include a plurality of memory blocks BLK1 to BLKz. Each memory block may have a two-dimensional or a three-dimensional structure. When the memory blocks have a three-dimensional structure as shown in FIG. 8, each memory block may include a plurality of memory cells stacked on a substrate. The memory cells are arranged in a +X direction, a +Y direction, and a +Z direction. The structure of each memory block will be described in more detail with reference to FIGS. 9 and 10.

FIG. 9 is a circuit diagram illustrating any one memory block BLKa of memory blocks BLK1 to BLKz of FIG. 8, in accordance with an embodiment of the present disclosure.

Referring to FIG. 9, the memory block BLKa may include a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings may be arranged in a row direction (i.e., the +X direction). In FIG. 9, two cell strings are illustrated as being arranged in a column direction (i.e., the +Y direction). However, this illustration is made for convenience of description, and it will be understood that three or more cell strings may be arranged in the column direction.

Each of the plurality of cell strings CS11 to CS1m and CS21 to CS2m may include at least one source select transistor SST, first to n-th memory cells MC1 to MCn, a pipe transistor PT, and at least one drain select transistor DST.

The select transistors SST and DST and the memory cells MC1 to MCn may have structures similar to each other. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between the common source line CSL and the memory cells MC1 to MCp.

In an embodiment, source select transistors of cell strings arranged in the same row are coupled to a source select line extending in a row direction, and source select transistors of cell strings arranged in different rows are coupled to different source select lines. In FIG. 9, source select transistors of the cell strings CS11 to CS1m in a first row are coupled to a first source select line SSL1. Source select transistors of the cell strings CS21 to CS2m in a second row are coupled to a second source select line SSL2.

In an embodiment, the source select transistors of the cell strings CS11 to CS1m and CS21 to CS2m may be coupled in common to a single source select line.

The first to n-th memory cells MC1 to MCn in each cell string are coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are successively arranged in a direction opposite to the +Z direction and are coupled in series between the source select transistor SST and the pipe transistor PT. The p+1-th to n-th memory cells MCp+1 to MCn are successively arranged in the +Z direction and are coupled in series between the pipe transistor PT and the drain select transistor DST. The first to p-th memory cells MC1 to MCp and the p+1-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

A gate of the pipe transistor PT of each cell string is coupled to a pipeline PL.

The drain select transistor DST of each cell string is coupled between the corresponding bit line and the memory cells MCp+1 to MCn. The cell strings arranged in the row direction are coupled to drain select lines extending in the row direction. Drain select transistors of the cell strings CS11 to CS1m in the first row are coupled to a first drain select line DSL1. Drain select transistors of the cell strings CS21 to CS2m in the second row are coupled to a second drain select line DSL2.

Cell strings arranged in the column direction may be coupled to bit lines extending in the column direction. In FIG. 9, cell strings CS11 and CS21 in a first column are coupled to a first bit line BL1. Cell strings CS1m and CS2m in an m-th column are coupled to an m-th bit line BLm.

Memory cells coupled to the same word line in cell strings arranged in the row direction form a single page. For example, memory cells coupled to the first word line WL1, among the cell strings CS11 to CS1m in the first row, form a single page. Memory cells coupled to the first word line WL1, among the cell strings CS21 to CS2m in the second row, form another single page. Cell strings arranged in the direction of a single row may be selected by selecting any one of the drain select lines DSL1 and DSL2. One page may be selected from among the selected cell strings by selecting any one of the word lines WL1 to WLn.

In an embodiment, even bit lines and odd bit lines may be provided in lieu of the first to m-th bit lines BL1 to BLm. Even-number-th cell strings of the cell strings CS11 to CS1m or CS21 to CS2m arranged in the row direction may be coupled to respective even bit lines. Odd-number-th cell strings of the cell strings CS11 to CS1m or CS21 to CS2m arranged in the row direction may be coupled to respective odd bit lines.

In an embodiment, at least one or more of the first to n-th memory cells MC1 to MCn may be used as a dummy memory cell. For example, the at least one or more dummy memory cells may be provided to reduce an electric field between the source select transistor SST and the memory cells MC1 to MCp. Alternatively, the at least one or more dummy memory cells may be provided to reduce an electric field between the drain select transistor DST and the memory cells MCp+1 to MCn. As the number of dummy memory cells is increased, the reliability in operation of the memory block BLKa may be increased, while the size of the memory block BLKa may be increased. As the number of dummy memory cells is reduced, the size of the memory block BLKa may be reduced, but the reliability in operation of the memory block BLKa may be reduced.

To efficiently control the at least one dummy memory cells, each of the dummy memory cells may have a required threshold voltage. Before or after an erase operation on the memory block BLKa is performed, program operations may be performed on all or some of the dummy memory cells. In the case where an erase operation is performed after a program operation has been performed, the dummy memory cells may have required threshold voltages by controlling a voltage to be applied to the dummy word lines coupled to the respective dummy memory cells.

FIG. 10 is a circuit diagram illustrating any one memory block BLKb of memory blocks BLK1 to BLKz of FIG. 8, in accordance with an embodiment of the present disclosure.

Referring to FIG. 10, a memory block BLKb may include a plurality of cell strings CS11′ to CS1m′ and CS21′ to CS2m′. Each of the cell strings CS11′ to CS1m′ and CS21′ to CS2m′ extends in the +Z direction. Each of the cell strings CS11′ to CS1m′ and CS21′ to CS2m′ may include at least one source select transistor SST, first to n-th memory cells MC1 to MCn, and at least one drain select transistor DST which are stacked on a substrate (not shown) provided in a lower portion of the memory block BLK1′.

The source select transistor SST of each cell string is coupled between the common source line CSL and the memory cells MC1 to MCn. The source select transistors of cell strings arranged in the same row are coupled to the same source select line. Source select transistors of the cell strings CS11′ to CS1m′ arranged in a first row may be coupled to a first source select line SSL1. Source select transistors of the cell strings CS21′ to CS2m′ arranged in a second row may be coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string are coupled in series between the source select transistor SST and the drain select transistor DST. Gates of the first to n-th memory cells MC1 to MCn are respectively coupled to first to n-th word lines WL1 to WLn.

The drain select transistor DST of each cell string is coupled between the corresponding bit line and the memory cells MC1 to MCn. Drain select transistors of cell strings arranged in the row direction may be coupled to drain select lines extending in the row direction. Drain select transistors of the cell strings CS11′ to CS1m′ in the first row are coupled to a first drain select line DSL1. Drain select transistors of the cell strings CS21′ to CS2m′ in the second row may be coupled to a second drain select line DSL2.

As a result, the memory block BLKb of FIG. 10 may have a circuit substantially similar to that of the memory block BLKa of FIG. 9. That is, the pipe transistor PT that is included in the memory block BLKa of FIG. 9 is excluded from each cell string in the memory block BLKb of FIG. 10.

In an embodiment, even bit lines and odd bit lines may be provided in lieu of the first to m-th bit lines BL1 to BLm. Even-number-th cell strings among the cell strings CS11′ to CS1m′ or CS21′ to CS2m′ arranged in the row direction may be coupled to the respective even bit lines, and odd-number-th cell strings among the cell strings CS11′ to CS1m′ or CS21′ to CS2m′ arranged in the row direction may be coupled to the respective odd bit lines.

In an embodiment, at least one or more of the first to n-th memory cells MC1 to MCn may be used as a dummy memory cell. For example, the at least one or more dummy memory cells may be provided to reduce an electric field between the source select transistor SST and the memory cells MC1 to MCn. Alternatively, the at least one or more dummy memory cells may be provided to reduce an electric field between the drain select transistor DST and the memory cells MC1 to MCn. As the number of dummy memory cells is increased, the reliability in operation of the memory block BLKb may be increased, while the size of the memory block BLKb may be increased. As the number of dummy memory cells is reduced, the size of the memory block BLKb may be reduced, but the reliability in operation of the memory block BLKb may be reduced.

To efficiently control the at least one dummy memory cells, each of the dummy memory cells may have a required threshold voltage. Before or after an erase operation on the memory block BLKb is performed, program operations may be performed on all or some of the dummy memory cells. In the case where an erase operation is performed after a program operation has been performed, the dummy memory cells may have required threshold voltages by controlling a voltage to be applied to the dummy word lines coupled to the respective dummy memory cells.

FIG. 11 is a diagram illustrating an example of the memory controller 200 of FIG. 1, in accordance with an embodiment of the present disclosure.

The memory controller 1000 is coupled to the host and the memory device 100. In response to a request from the host, the controller 1000 may access the memory device 100. For example, the memory controller 1000 may control a write operation, a read operation, an erase operation, and a background operation of the memory device 100. The memory controller 1000 may provide an interface between the memory device 100 and the host. The memory controller 1000 may drive firmware for controlling the memory device 100.

Referring to FIG. 11, the memory controller 1000 may include a processor 1010, a memory buffer 1020, an error correction code (ECC) circuit 1030, a host Interface 1040, a buffer control circuit 1050, a memory interface 1060, and a bus 1070.

The bus 1070 may provide a channel between the components of the memory controller 1000.

The processor 1010 may control the overall operation of the memory controller 1000 and perform a logical operation. The processor 1010 may communicate with the external host through the host interface 1040, and communicate with the memory device 100 through the memory interface 1060. In addition, the processor 1010 may communicate with the memory buffer 1020 through the buffer control circuit 1050. The processor 1010 may control the operation of the storage device 50 using the memory buffer 1020 as an operation memory, a cache memory, or a buffer memory.

The processor 1010 may perform the function of a flash translation layer (FTL). The processor 1010 may translate a logical block address (LBA), provided by the host, into a physical block address (PBA) through the FTL. The FTL may receive the LBA using a mapping table and translate the LBA into the PBA. An address mapping method using the FTL may be modified in various ways based on the unit of mapping. Representative address mapping methods may include a page mapping method, a block mapping method, and a hybrid mapping method.

The processor 1010 may randomize data received from the host. For example, the processor 1010 may use a randomizing seed to randomize data received from the host. Randomized data may be provided to the memory device 100 as data to be stored, and may be programmed to the memory cell array.

During a read operation, the processor 1010 may derandomize data received from the memory device 100. For example, the processor 1010 may use a derandomizing seed to derandomize data received from the memory device 100. Derandomized data may be output to the host.

In an embodiment, the processor 1010 may drive software or firmware to perform the randomizing operation or the derandomizing operation.

The memory buffer 1020 may be used as an operation memory, a cache memory, or a buffer memory of the processor 1010. The memory buffer 1020 may store codes and commands to be executed by the processor 1010. The memory buffer 1020 may store data to be processed by the processor 1010. The memory buffer 1020 may include a static RAM (SRAM) or a dynamic RAM (DRAM).

The ECC circuit 1030 may perform error correction. The ECC circuit 1030 may perform an ECC encoding operation based on data to be written to the memory device 100 through the memory interface 1060. ECC encoded data may be transmitted to the memory device 100 through the memory interface 1060. The ECC circuit 1030 may perform an ECC decoding operation on data received from the memory device 100 through the memory interface 1060. For example, the ECC circuit 1030 may be included in the memory interface 1060 as a component of the memory interface 1060.

The host interface 1040 may communicate with the external host under control of the processor 1010. The host interface 1040 may perform communication using at least one of various communication methods such as a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), a universal flash storage (UFS), a secure digital (SD), multiMedia card (MMC), an embedded MMC (eMMC), a dual in-line memory module (DIMM), a registered DIMM (RDIMM), and a load reduced DIMM (LRDIMM).

The buffer control circuit 1050 may control the memory buffer 1020 under control of the processor 1010.

The memory interface 1060 may communicate with the memory device 100 under control of the processor 1010. The memory interface 1060 may communicate a command, an address, and data with the memory device 100 through the channel.

For example, the memory controller 1000 may include neither the memory buffer 1020 nor the buffer control circuit 1050.

For example, the processor 1010 may use codes to control the operation of the memory controller 1000. The processor 1010 may load codes from a nonvolatile memory device (e.g., a read only memory) provided in the memory controller 1000. Alternatively, the processor 1010 may load codes from the memory device 100 through the memory interface 1060.

For example, the bus 1070 of the memory controller 1000 may be divided into a control bus and a data bus. The data bus may transmit data in the memory controller 1000. The control bus may transmit control information such as a command and an address in the memory controller 1000. The data bus and the control bus may be separated from each other and may neither interfere with each other nor affect each other. The data bus may be coupled to the host interface 1040, the buffer control circuit 1050, the ECC circuit 1030, and the memory interface 1060. The control bus may be coupled to the host interface 1040, the processor 1010, the buffer control circuit 1050, the memory buffer 1020, and the memory interface 1060.

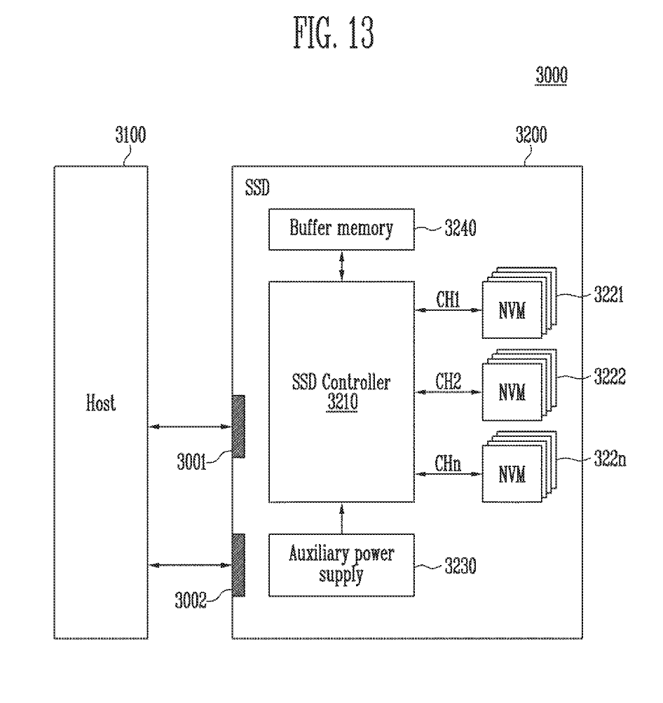

FIG. 12 is a block diagram illustrating a memory card system 2000 to which a storage device in accordance with an embodiment of the present disclosure is applied.

Referring FIG. 12, the memory card system 2000 may include a memory controller 2100, a memory device 2200 and a connector 2300.

The memory controller 2100 is coupled to the memory device 2200. The memory controller 2100 may access the memory device 2200. For example, the memory controller 2100 may control a read operation, a write operation, an erase operation, and a background operation of the memory device 2200. The memory controller 2100 may provide an interface between the memory device 2100 and the host. The memory controller 2100 may drive firmware for controlling the memory device 2200. The memory controller 2100 may be embodied in the same manner as that of the memory controller 200 described with reference to FIG. 1.

In an embodiment, the memory controller 2100 may include components such as a random access memory (RAM), a processor, a host interface, and a memory interface, and an ECC circuit.

The memory controller 2100 may communicate with an external device through the connector 2300. The memory controller 2100 may communicate with an external device (e.g., a host) based on a specific communication protocol. In an embodiment, the memory controller 2100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) protocols. In an embodiment, the connector 2300 may be defined by at least one of the above-described various communication protocols.

In an embodiment, the memory device 2200 may be implemented as any of various nonvolatile memory devices, such as an electrically erasable and programmable ROM (EEPROM), a NAND flash memory, a NOR flash memory, a phase-change RAM (PRAM), a resistive RAM (ReRAM), a ferroelectric RAM (FRAM), and a spin-torque magnetic RAM (STT-MRAM).

In an embodiment, the memory controller 2100 and the memory device 2200 may be integrated into a single semiconductor device to form a memory card. For example, the memory controller 2100 and the memory device 2200 may be integrated into a single semiconductor device to form a memory card such as a personal computer memory card international association (PCMCIA), a compact flash card (CF), a smart media card (SM or SMC), a memory stick, a multimedia card (MMC, RS-MMC, or MMCmicro), a SD card (SD, miniSD, microSD, or SDHC), or a universal flash storage (UFS).

FIG. 13 is a block diagram illustrating a solid state drive (SSD) system 3000 to which the storage device in accordance with an embodiment of the present disclosure is applied.

Referring to FIG. 13, the SSD system 3000 may include a host 3100 and an SSD 3200. The SSD 3200 may exchange signals SIG with the host 3100 through a signal connector 3001 and may receive power PWR through a power connector 3002. The SSD 3200 may include an SSD controller 3210, a plurality of flash memories 3221 to 322n, an auxiliary power supply 3230, and a buffer memory 3240.

In an embodiment, the SSD controller 3210 may perform the function of the memory controller 200, described above with reference to FIG. 1.

The SSD controller 3210 may control the plurality of flash memories 3221 to 322n in response to the signals SIG received from the host 3100. In an embodiment, the signals SIG may be signals based on the interfaces of the host 3100 and the SSD 3200. For example, the signals SIG may be signals defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) interfaces.

The auxiliary power supply 3230 may be coupled to the host 3100 through the power connector 3002. The auxiliary power supply 3230 may be supplied with power PWR from the host 3100 and may be charged. The auxiliary power supply 3230 may supply the power of the SSD 3200 when the supply of power from the host 3100 is not smoothly performed. In an embodiment, the auxiliary power supply 3230 may be positioned inside the SSD 3200 or positioned outside the SSD 3200. For example, the auxiliary power supply 3230 may be disposed in a main board and may supply auxiliary power to the SSD 3200.

The buffer memory 3240 functions as a buffer memory of the SSD 3200. For example, the buffer memory 3240 may temporarily store data received from the host 3100 or data received from the plurality of flash memories 3221 to 322n or may temporarily store metadata (e.g., mapping tables) of the flash memories 3221 to 322n. The buffer memory 3240 may include volatile memories such as DRAM, SDRAM, DDR SDRAM, LPDDR SDRAM, and GRAM or nonvolatile memories such as FRAM, ReRAM, STT-MRAM, and PRAM.

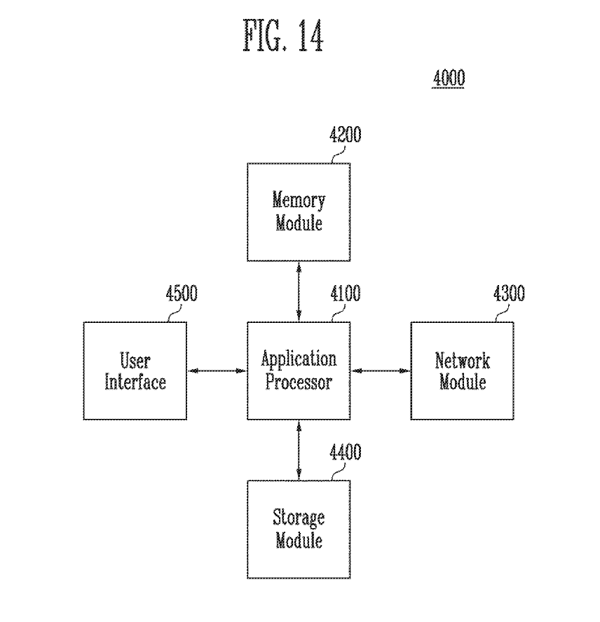

FIG. 14 is a block diagram illustrating a user system 4000 to which the storage device in accordance with an embodiment of the present disclosure is applied.

Referring to FIG. 14, the user system 4000 may include an application processor 4100, a memory module 4200, a network module 4300, a storage module 4400, and a user interface 4500.

The application processor 4100 may run components included in the user system 4000, an operating system (OS) or a user program. In an embodiment, the application processor 4100 may include controllers, interfaces, graphic engines, etc. for controlling the components included in the user system 4000. The application processor 4100 may be provided as a system-on-chip (SoC).

The memory module 4200 may function as a main memory, a working memory, a buffer memory or a cache memory of the user system 4000. The memory module 4200 may include volatile RAMs such as DRAM, SDRAM, DDR SDRAM, DDR2 SDRAM, DDR3 SDRAM, LPDDR SDARM, and LPDDR3 SDRAM, or nonvolatile RAMs such as PRAM, ReRAM, MRAM, and FRAM. In an embodiment, the application processor 4100 and the memory module 4200 may be packaged based on package-on-package (POP) and may then be provided as a single semiconductor package.

The network module 4300 may communicate with external devices. For example, the network module 4300 may support wireless communication, such as code division multiple access (CDMA), global system for mobile communication (GSM), wideband CDMA (WCDMA), CDMA-2000, time division multiple access (TDMA), long term evolution (LTE), WiMAX, WLAN, UWB, Bluetooth, or Wi-Fi communication. In an embodiment, the network module 4300 may be included in the application processor 4100.

The storage module 4400 may store data therein. For example, the storage module 4400 may store data received from the application processor 4100. Alternatively, the storage module 4400 may transmit the data stored in the storage module 4400 to the application processor 4100. In an embodiment, the storage module 4400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In an embodiment, the storage module 4400 may be provided as a removable storage medium (i.e., removable drive), such as a memory card or an external drive of the user system 400.

In an embodiment, the storage module 4400 may include a plurality of nonvolatile memory devices, and each of the plurality of nonvolatile memory devices may be operated in the same manner as that of the memory device 100, described above with reference to FIGS. 2 and 5. The storage module 4400 may be operated in the same manner as that of the storage device 50, described above with reference to FIG. 1.

The user interface 4500 may include interfaces which input data or instructions to the application processor 4100 or output data to an external device. In an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric device. The user interface 4500 may further include user output interfaces such as an a liquid crystal display (LCD), an organic light emitting diode (OLED) display device, an active matrix OLED (AMOLED) display device, an LED, a speaker, and a motor.

Various embodiments of the present disclosure provide a storage device including a memory controller configured to control a background erase operation, and a method of operating the storage device.

While the exemplary embodiments of the present disclosure have been disclosed for illustrative purposes, those skilled in the art will appreciate that various modifications, additions and substitutions are possible. Therefore, the scope of the present disclosure must be defined by the appended claims and equivalents of the claims rather than by the description preceding them.

In the above-discussed embodiments, all steps may be selectively performed or skipped. In addition, the steps in each embodiment may be not always performed in regular order. Furthermore, the embodiments disclosed in the present specification and the drawings aims to help those with ordinary knowledge in this art more clearly understand the present disclosure rather than aiming to limit the bounds of the present disclosure. In other words, one of ordinary skill in the art to which the present disclosure belongs will be able to easily understand that various modifications are possible based on the technical scope of the present disclosure.

Embodiments of the present disclosure have been described with reference to the accompanying drawings, and specific terms or words used in the description should be construed in accordance with the spirit of the present disclosure without limiting the subject matter thereof. It should be understood that many variations and modifications of the basic inventive concept described herein will still fall within the spirit and scope of the present disclosure as defined in the appended claims and their equivalents.

What is claimed is:

1. A storage device comprising:
a memory device including a plurality of memory blocks; and
a memory controller configured to control the memory device to perform a background erase operation on at least one free block of the plurality of memory blocks based on information about a size of write data to be provided to the memory device.

2. The storage device according to claim 1, wherein, when a normal operation command is inputted from the memory controller while the background erase operation is performed, the memory device suspends the background erase operation in response to input of a confirm command of the normal operation command.

3. The storage device according to claim 1, wherein the memory controller comprises:
a background erase operation controller configured to provide triggering information instructing the background erase operation to be performed based on the information about the size of the write data; and
a command generator configured to generate a background erase operation command instructing the background erase operation to be performed on the at least one free block based on the triggering information.

4. The storage device according to claim 1, wherein the background erase operation controller generates write count information obtained by accumulating the information about the size of the write data, and determines whether the write count information exceeds a preset reference value.

5. The storage device according to claim 4, wherein the preset reference value is a value corresponding to a size of any one of the plurality of memory blocks.

6. The storage device according to claim 4, wherein the memory controller further comprises a write count information storage configured to store the write count information.

7. The storage device according to claim 3, wherein the memory controller further comprises a block management component configured to store a free block list which includes information about addresses of a plurality of free blocks included in the memory device.

8. The storage device according to claim 7, wherein, in response to the triggering information, the command generator generates the background erase operation command for a free block having a lowest erase operation count among the plurality of free blocks included in the free block list.

9. The storage device according to claim 2, wherein the normal operation command includes a first command, and a second command indicating that an address and data needed to perform the first command have been completely inputted.

10. The storage device according to claim 9,
wherein the first command comprises a start command indicating a type of the normal operation command, and
wherein the second command comprises the confirm command.

11. The storage device according to claim 2, wherein the normal operation command comprises a command corresponding to any one of a program operation, a read operation, and an erase operation.

12. A method of operating a memory controller configured to control a memory device including a plurality of memory blocks, the method comprising:
obtaining information about a size of write data to be provided to the memory device; and
instructing the memory device to perform a background erase operation on at least one free block of the plurality of memory blocks based on the information about the size of the write data.

13. The method according to claim 12, wherein the instructing comprises:
generating write count information obtained by accumulating the information of the size of the write data; and
providing a background erase command instructing the background erase operation to be performed on the at least one free block depending on whether the write count information exceeds a preset reference value.

14. The method according to claim 13, wherein the providing comprises:
generating triggering information instructing the background erase operation to be performed when the write count information exceeds the preset reference value; and
generating a background erase operation command instructing the background erase operation to be performed on the at least one free block based on the triggering information.

15. The method according to claim 14, wherein the generating of the background erase operation command comprises generating the background erase operation command for a free block having a lowest erase operation count among a plurality of free blocks included in a free block list including information about addresses of the plurality free blocks included in the memory device.

16. The method according to claim 12, wherein, when a normal operation command is inputted from the memory controller while the background erase operation is performed, the memory device suspends the background erase operation in response to input of a confirm command of the normal operation command.

17. A memory system comprising:
a memory device including a plurality of memory blocks; and
a controller configured to control, when accumulated size of data stored in the memory blocks becomes greater than storage capacity of a single memory block, the memory device to perform a background erase operation on one or more memory blocks storing invalid data among the memory blocks while the memory device is idle.
